(19) United States
(12) Patent Application Publication
(10) Pub. No.: US 2011/0079270 A1
(43) Pub. Date: Apr. 7, 2011

(54) CONCENTRATOR PHOTOVOLTAIC CELL

(75) Inventor: Thomas N. D. Tibbits, London (GB)

(73) Assignee: QuantaSol Limited

(21) Appl. No.: 12/912,442

(22) Filed: Oct. 26, 2010

Related U.S. Application Data
(63) Continuation of application No. PCT/GB2009/001073, filed on Apr. 27, 2009.

(30) Foreign Application Priority Data
Apr. 28, 2008 (GB) GB 0807693.7

(51) Int. Cl. H01L 31/052

(52) U.S. Cl. 136/246

(57) ABSTRACT

There is disclosed a concentrator solar cell, having one or more radially elongate bus bars extending into a central region of the cell for collecting current from gridlines. Each bus bar terminates in a separate bond pad region at a periphery of the device.

### CROSS-REFERENCE TO RELATED PATENT APPLICATIONS

The present application is a Continuation of International Application PCT/GB2009/001073, filed Apr. 27, 2009, which claims priority to United Kingdom Application GB 0807693.7, filed Apr. 28, 2008. The entire disclosures of International Application PCT/GB2009/001073 and United Kingdom Application GB 0807693.7 are incorporated herein by reference in their entireties.

### BACKGROUND

The present invention relates to photovoltaic cells, and in particular to the arrangement of busbar and gridline structures on the front surfaces of such cells for coupling the photogenerated current with an external load, and in particular for concentrator photovoltaic cells for use in concentrator systems which intensify incident light for delivery to the cell.

A solar cell, or more generally a photovoltaic cell, usually comprises two or more layers of semiconductor material from which charge carriers are liberated by incident light. One or more semiconductor junctions between the layers operate to separate the liberated charge carriers which then move to electrodes thereby providing electrical power.

A variety of different semiconductor materials and layer structures are known in the art. Some approaches aim to use cheap materials and manufacturing methods to provide large solar cell surface areas, albeit operating at relatively low efficiencies such as converting around 7% of the incident solar energy into electrical power as is typical for a contemporary amorphous silicon solar cell.

Other approaches use much more expensive materials such as gallium arsenide and variants thereof and complex manufacturing processes, and aim for efficiencies of greater than 30%, often using multiple semiconductor junctions to absorb light of successively longer wavelengths. For some devices, increasing the concentration of the incident light using optical arrangements to concentrate the available light onto very small photovoltaic cells, typically by a factor of around ×100 to ×1000, can significantly enhance the conversion efficiency. However specific design considerations apply to concentrator solar cells adapted to operate under such high illumination levels, and it is notable that the “Solar Efficiency Tables” published periodically in Progress in Photovoltaics: Research and Applications, e.g. 2004; 12:55-62, list concentrator cells and modules separately to cells and modules suitable for AM1.5 spectrum illumination. The costs of manufacture of solar cells using materials such as Gallium Arsenide, and of constructing the more complex structures, can also be mitigated by using light concentration techniques. Typical sizes of individual concentrator solar cells range from about 0.1 mm² to 200 mm²

A consequence of the high illumination levels and the high conversion efficiency of a concentrator cell is that large currents are generated in small areas, typically in the region of a few Amps per square centimeter. On the back surface of the cell there is usually no need for transparency, and a planar metallic electrode covering the whole cell surface can be used. On the front surface, where light is to enter the cell, a minimum of metallic coverage is desired to minimize shading of the semiconductor layers. Conversely, a low resistance Ohmic contact is required in order to efficiently carry the large electrical currents which can be generated. The power losses due to the impedance of surface electrodes can be significant, and the subject has been considered for example in Rey-Stolle and Algora, IEEE Transactions on Electron Devices, Vol 49, No. 10, October 2002, pages 1709-1714, and in Algora and Diaz, Prog. Photovolt. Res. Appl. 2000; 8:211-225.

An effective Ohmic contact of the front plane electrode structure to the semiconductor is generally achieved using a plurality of fine metallic gridlines, often in silver or gold, deposited on the semiconductor surface. These gridline structures are frequently referred to as fingers, although it should be noted that they may be provided in a variety of geometries, for example electrically connected with the rest of the electrode structure only at one end or interlinking with other gridlines and parts of the electrode structure in various ways, in straight or curved sections, as a substantially parallel array, a rectilinear grid, and in many other patterns. In a concentrator cell the gridlines are typically 1 μm to 40 μm, and sometimes less than 1 μm wide in the front plane of the cell and a few μm thick. The fine gridlines connect to one or more much larger metallic busbar structures which have the dual roles of collecting photocurrent from, or delivering the current to, the gridlines, and of permitting reliable external electrical connection to the cell for example by coupling to external fine gold wires. Typical busbar widths of at least 50 μm, and typically up to 500 μm or so, are usually needed to permit such connections to be made reliably.

The front surface of a typical prior art concentrator solar cell 10 is shown in FIG. 1. This cell is provided with a busbar and gridlines similar to those shown in the above Rey-Stolle and Algora, and Algora and Diaz references. The cell is square with a side of 1.2 mm, and is one of many thousands of such cells cut from a single semiconductor wafer following detailed manufacturing process steps, before housing in a package or solar concentrator module, and connection using gold wires to electrical terminals of the package. On the front surface can be seen a unitary busbar structure 12 which is a continuous metal strip running along the four sides of the cell at the outside edge. This busbar has a width in the plane of the front surface of about 100 μm. A plurality of gridlines extend from the bus bar across the front surface of the cell, generally parallel to an outside edge before turning through a right angle to return to the adjacent, perpendicular edge. These gridlines have a width of about 1 to 20 μm.

To make an electrical connection between the bus bar and an external electrical load, gold wires 16 are bonded at several points 18 to the bus bar. Of a total area of front plane of 1.44 mm² available for receiving light in the illustrated structure, only about 1.0 mm² is free from shadowing by the busbar structure.

The front surface of another prior art cell 20, which is discussed in International Application PCT/US2004/020274, is illustrated in FIG. 2. This concentrator cell is of similar size and general construction to that of FIG. 1. However, the busbar 22 extends only along one side of the cell, and an insulator layer 24 lies between the busbar and the semiconductor surface so as to reduce damage which might otherwise be caused by heat generated at tiny localized current shunts which tend to occur at points of imperfection in the semiconductor lattice.

Cell 20 comprises an array of parallel silver gridline structures 26, disposed across the face of the cell, each gridline coupling to the busbar 22 at one end. Each gridline is about 15 μm across in the plane of the cell and about 5 μm thick. However, each gridline extends across nearly the full width of the cell, increasing the Ohmic resistance of these already fine structures.

It would be desirable to reduce the effect of shading of a concentrator solar cell by front plane electrode busbar structures, to thereby increase the amount of light entering the active semiconductor layers, while maintaining an electrode structure capable of carrying the required very high currents and permitting reliable external connections. This problem is relevant to the design of a concentrator solar cell because of the high illumination intensities giving rise to very high current densities with associated resistive losses, which are proportional to the square of the current, being very significant.

It would also be desirable to provide a concentrator solar cell in which the front plane electrode structure was more suitable for carrying high localized currents generated by areas of more intense illumination on the surface of the cell, especially where the positions of such high intensity areas are unpredictable or variable, as is typical in many concentrator solar cell systems.

### SUMMARY

An exemplary embodiment relates to a concentrator photovoltaic cell that includes a front plane through which light passes into the photovoltaic cell for the generation of a photocurrent. The concentrator photovoltaic cell also includes a plurality of conductive gridlines disposed across the front plane so as to communicate the photocurrent with the front plane and a plurality of separate conductive busbars disposed across the front plane and coupled to communicate the photocurrent with the gridlines. Each busbar comprises a bondpad region disposed at a periphery of the front plane for coupling the photocurrent to an external load, and wherein each busbar is elongate in a radial direction and extends into a central region of the front plane.

Another exemplary embodiment relates to a solar photovoltaic system that includes a photovoltaic cell and an optical concentrator arranged to deliver sunlight having a concentrated intensity of at least one hundred suns to said photovoltaic cell. The photovoltaic cell includes a front plane through which light passes into the photovoltaic cell for the generation of a photocurrent, a plurality of conductive gridlines disposed across the front plane so as to communicate the photocurrent with the front plane, and a plurality of separate conductive busbars disposed across the front plane and coupled to communicate the photocurrent with the gridlines. Each busbar comprises a bondpad region disposed at a periphery of the front plane for coupling the photocurrent to an external load, and wherein each busbar is elongate in a radial direction and extends into a central region of the front plane.

Another exemplary embodiment relates to a solar photovoltaic system that includes a photovoltaic cell having a front surface with an area of less than 200 mm² and an optical concentrator arranged to receive incident sunlight and to deliver the sunlight concentrated by a factor of at least fifty to a front plane of the cell whereby the photovoltaic cell generates an electrical current. The photovoltaic cell further includes a plurality of metallic gridline structures disposed at the front plane of the cell that are arranged to carry the electrical current into or out of the front plane, and one or more separate radially elongate metallic busbars also disposed at the front plane of the cell and arranged to carry the electrical current to or from the gridline structures. Each busbar extends from a peripheral region into a central region of the front surface of the cell.

### BRIEF DESCRIPTION OF THE DRAWINGS

Embodiments of the invention will now be described, by way of example only, with reference to the accompanying drawings of which:

FIGS. 1 and 2 illustrate prior art concentrator photovoltaic cells, and in particular gridline structures, busbar, and external wire connections for collecting current;

FIG. 3 illustrates a photovoltaic system including an optical concentrator directing light onto a plurality of concentrator solar cells;

FIG. 4 illustrates a first concentrator cell embodying the invention, in which four radially elongate busbars extend from a periphery to a central region of the front surface of the cell;

FIG. 5 illustrates a package housing the concentrator cell of FIG. 4;

FIG. 6 illustrates a second concentrator cell which embodies the invention, in which a single radially elongate busbar extends from a periphery to a central region;

FIG. 7 illustrates a further concentrator cell which embodies the invention in which four radially elongate busbars are provided with a concave taper and join in a central region of the cell; and

FIG. 8 illustrates a further concentrator cell which embodies the invention.

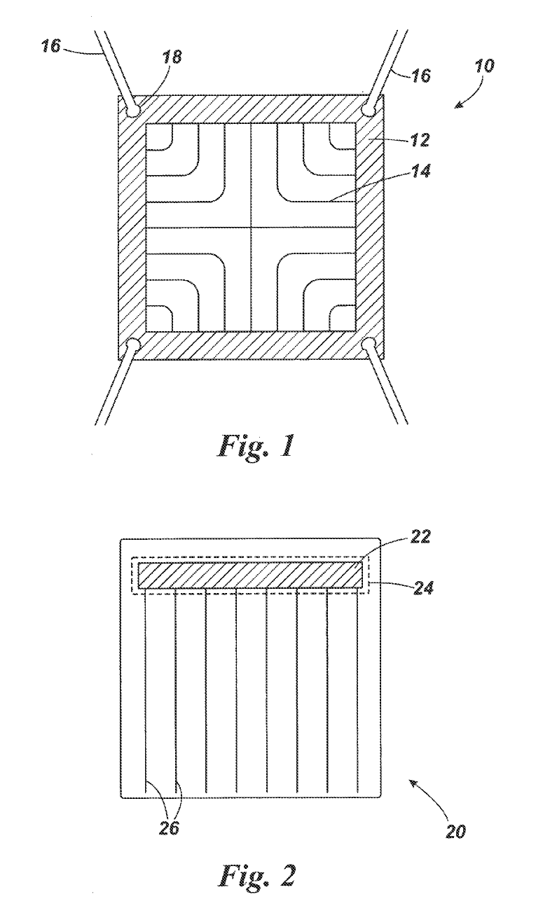

### DETAILED DESCRIPTION

The invention provides a concentrator solar cell, or photovoltaic cell, comprising one or more elongate busbar elements each extending radially inwards from a different part of a periphery of the cell. Each busbar comprises a bondpad region at the peripheral end, suitable for external electrical connection. Gridlines, typically much finer than the busbars, are connected to the one or more busbars and extend across the solar cell to couple the electrical current generated by the cell with the one or more busbars.

Each busbar may be generally tapered away from the bondpad, for example in a dart or wedge shape. Where there are two or more radially extending busbars these may join in a central region of the cell, or may terminate separately.

Even if joined centrally, busbar elements may be separate in the sense of being separated in the peripheral region, or at least away from the central region of the cell. In some described embodiments there are four busbars, each extending radially inward from a respective side of a substantially square or rectangular solar cell. Four busbars may thereby form a closed or centrally open “+” or “X” shape across the cell. However, as few as one, or many more than four busbars may be provided.

Noting that a metallic busbar structure generally shades the underlying photovoltaic structure, the described busbar arrangements may be used to decrease the amount of shading while maintaining adequate current carrying capacity. The elongate radial distribution of separate busbar elements may also improve the response of the cell to uneven illumination frequently found in concentrator systems.

The gridline structures also cause some shading of the cell, so that appropriate sizes, spacings and numbers of gridlines to balance the effect of shading with the required current carrying capacity should be sought. Typically, there will be at least ten gridline connections to each busbar. High current densities in a concentrator cell mean that the gridlines may cover an area of the cell which is at least 1%, and optionally at least 10% or at least 20% of the size of the surface which is open to receive illumination.

According to one aspect, the invention provides a concentrator solar cell comprising: a front plane through which light enters the solar cell for the generation of electrical current; and a metallic front plane electrode structure. The electrode structure includes a plurality of metallic gridlines disposed across the front plane so as to couple said electrical current with (into or out of) said front plane; and one or more metallic busbars connected to said gridlines so as to couple said electrical current with external connections. Each busbar is radially elongate, extending from a periphery of the cell into a central region. Each busbar comprises a bond pad region, for coupling with an external connection, the bondpad region being disposed at the peripheral end of the busbar.

The front plane may be a front surface of a semiconductor material onto which the busbar and gridline structures are placed. However, it will frequently be the case that further layers are disposed over the electrode structures which will therefore be buried within the solar cell device.

The central region may be defined, for example, as no more than the central 50% area of the front plane, or more preferably no more than the central 25% area of the front plane. Similarly, each radially elongate bus bar may be required to extend at least 25%, or more preferably at least 40% across the front plane. In contrast, each separate bus bar may be required to extend by no more than 10% across the front plane perpendicular to the direction of radial elongation. Typically the broadest part of the busbar in this sense is expected to be the bondpad region at the cell periphery.

The concentrator solar cell may have a front plane surface area of less than 200 mm², less than 100 mm², and frequently less than about 10 mm², and may comprise a photovoltaic structure formed from III-V semiconductor materials such as GaAs and variants thereof, which may typically be formed on a gallium arsenide or Germanium substrate. Typically, the semiconductor layers of the concentrator cell, especially the layers of the one or more photovoltaic junctions, will be epitaxially grown, so that the device is monocrystalline, or monolithic.

Each bondpad region at the periphery of the front plane should be of a size suitable for making reliable external connections, for example to metallic wires, in order to carry the current generated by the cell, and is preferably at least 25 μm, and more typically about 100 μm across. Each gridline may typically be around 0.5 to 15 μm across.

The concentrator photovoltaic cell may be used in a system comprising an optical concentrator adapted to concentrate incident light onto the solar cell. The concentration factor may preferably be at least fifty, and more preferably at least one hundred, across the front surface of the cell, although the concentration factor may vary across the surface. An array of such solar cells may be used. Separate external connections, such as metallic wires, may be used to couple the generated current between an external load and each busbar, by attachment to the bondpad.

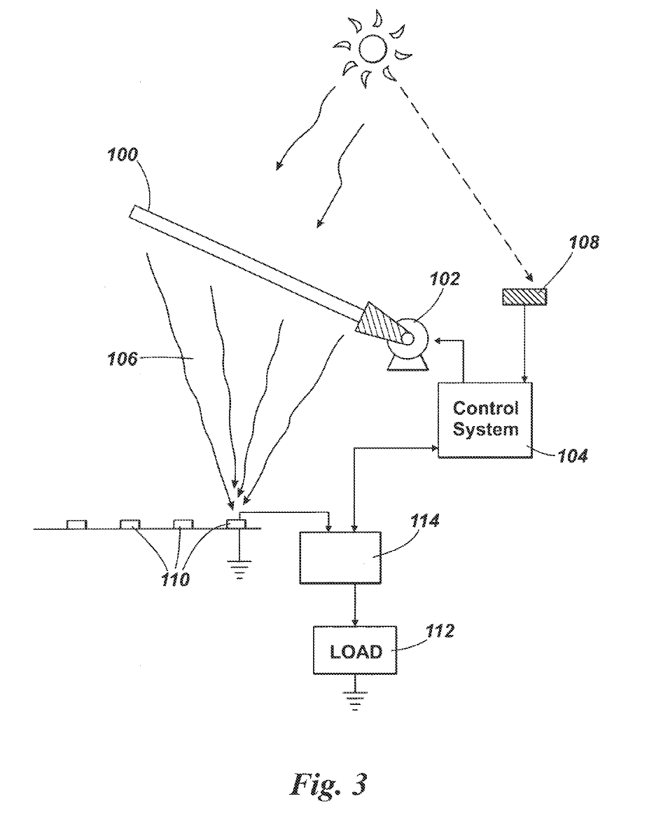

Referring now to FIG. 3 there is shown in schematic form a typical concentrator photovoltaic system. An optical concentrator 100 is directed by a mechanical driver 102 under control of a microprocessor control system 104 to direct concentrated sunlight 106 onto the front surface of a concentrator photovoltaic cell 110, for example in response to a sensor 108 which senses the relative position of the sun. The concentrator photovoltaic cell 110 generates electrical power, the delivery of which to a load 112 is managed by power circuitry 114, which may also be under control of the control system 104.

The concentrator may typically take the form of one or more mirrors, or one or more lenses such as Fresnel lenses. The sunlight arriving at the optical concentrator 100 may typically be concentrated by a factor of at least ×50, and more frequently between ×100 and ×1000 or greater by the time it reaches the concentrator solar cell 110. The system may include a large number of separate concentrator cells 110, for example a line of cells disposed under an elongate Fresnel lens, or a cluster of cells at the focus of a large concave mirror.

Each concentrator cell is adapted to work efficiently at high illumination intensities, and may require cooling. Each concentrator cell will typically have an efficiency of conversion of solar energy to electrical energy of greater than 20%, and more preferably greater than 30%. Such concentrator cells are typically constructed using Gallium Arsenide or other III-V materials for the semiconductor layers and substrate. Germanium may also be used as a substrate. Exemplary cell structures are described, for example, in WO03/012881, where a photovoltaic cell incorporating alternating, strain balanced InGaAs and GaAsP layers, between GaAs or InP bulk semiconductor regions, is described. Typically, the semiconductor layers of the cell will be formed monolithically, using epitaxial growth techniques, so as to preserve the monocrystalline nature of the whole monolith.

Each concentrator cell is small, having a front surface area of less than about 200 mm², and more typically between about 0.1 mm² and 100 mm². Typically, a large number of such cells may be fabricated on and cut from a single semiconductor wafer substrate.

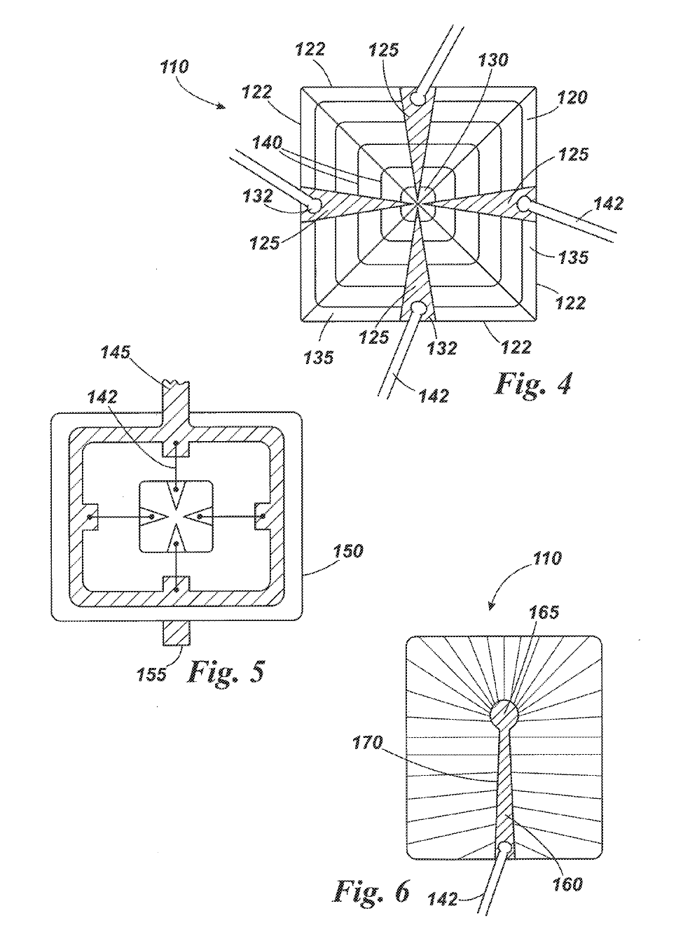

A front plane of a concentrator cell according to a first embodiment is shown in FIG. 4. The front plane of the cell is approximately square with sides each of length 1.2 mm. From the centre of each side 122, at the periphery 135 of the front plane 120, a radially elongate busbar 125 extends to a central region 130 of the front face. Each busbar is in the shape of a wedge, dart or arrowhead, tapering from the periphery 135 to the central region. The busbars 125 may extend from the very edges 122 of the cell or from a small distance within the edges. The busbars 125 may or may not extend to join each other at the centre.

Between the busbars extends a network of gridlines 140, adapted to collect the photocurrent from or to deliver the photocurrent to the front surface of the cell (the direction of current flow depends on the underlying photovoltaic structure). The figure is not intended to illustrate the actual thicknesses, or optimal numbers and spacings of the gridlines, which may be chosen in a conventional manner. In the embodiment of FIG. 4 the gridlines are disposed in a generally parallel manner to the sides of the front face, joining the busbars, and undergoing right angle turns at the diagonals which are also provided with radially directed gridlines extending inwards from each corner of the front plane to the centre. Typically, at least eight gridlines may connect to a busbar.

To carry sufficient current to operate under high illuminations, the total gridline area may be more than 1%, more than 10%, or perhaps more than 20% of the exposed surface of the cell which receives illumination, and may typically be between 1% and 10%.

In the example of FIG. 4 each busbar has a width of about 100 μm at the periphery, tapering with straight sides to a point at the centre of the front surface 120, so that the four busbars have a total surface area of about 0.12 mm². The width of each gridline element is about 15 μm, and six gridline elements extend from each side of each busbar in the pattern described above, so that the total surface area of the gridlines is about 0.2 mm².

Each busbar terminates, at the peripheral end, in a broad bondpad region 132 suitable for connection to an external conductor, in order to couple the concentrator cell to an external electrical load. One end of a gold wire 142 or other electrical conductor is bonded to the bondpad region of each busbar. Referring to FIG. 5, the other ends of these wires couple electrically to one or more electrical terminals 145 of a package 150 within which the cell is mounted. The concentrator cell is also provided with an electrode structure at a back plane, opposite to said front plane. This back electrode structure may typically be provided by a metallised layer extending across the whole of the device on the reverse side. The back electrode is also connected to a further electrical terminal 155 of the package.

The semiconductor surfaces to which the front and back electrode structures are applied may also be covered with further layers, such as protective transparent layers at the front of the device. The invention may be also be used in more complex arrangements, for example where busbar and gridline structures are sandwiched between two photovoltaic structures.

The semiconductor layers of a concentrator photovoltaic cell such as that described above with reference to FIG. 4 may be grown in an epitaxial reactor from III-V semiconductor materials such as GaAs, in manners well known in the art. The back surface electrode may then be metallized to the semiconductor substrate by sputtering or thermal evaporation, using metals such as Ti, Pt, Au, Ni or Ge. The overall thickness of the back surface electrode may be 1 to 3 μm. The front surface electrode is patterned to minimize shading and electrical resistance losses as described herein.

The patterning of the front plane electrode may be achieved using conventional photolithographic techniques, for example the following. Starting with a wafer on which the required semiconductor structures have already been prepared, 50 nm layers of titanium, then platinum, then gold are sputtered onto the front semiconductor surface. A negative photoresist is spun onto the sputtered metal surface. An aligned mask is used to pattern the photoresist according to the desired pattern of busbars and gridlines. The photoresist is developed, and gold is electroplated in the pattern on the photoresist, to a thickness of several micrometers. The photoresist is stripped, and the thin (approx 50 nm) sputtered metal layer that has not been gold electroplated is ion milled. The wafer is then prepared for mesa etching (photoresist, mask expose, develop). The mesa etch is carried out, the photoresist is stripped and the semiconductor cap is etched. An AR dielectric coating is applied using silicon nitride and silica (other materials which could be used include Al₂O₃, Ta₂O₅, MgF₂, ZnS, ZnO, TiO₂ etc). Photoresist is spun on to define contact pads on the busbars. The photoresist is developed, and the AR coating is etched. The wafer is then cleaned, and cleaved or sawn to separate the individual concentrator photovoltaic cells.

The front surface of a concentrator cell according to the invention may be patterned in various ways, and another example is shown in FIG. 6. A single radially elongated busbar 160 extends from an edge of the cell 110, tapering towards the centre of the front surface, and expanding into a rounded head 165 at the central end of the busbar just beyond the centre of the surface. The busbar is thus in the shape of a keyhole. Gridline structures extend laterally outwards from the straight, tapering sides 170 of the busbar, and radially outwards from the rounded head 165. A single connecting wire 140 carries photocurrent to or away from the busbar.

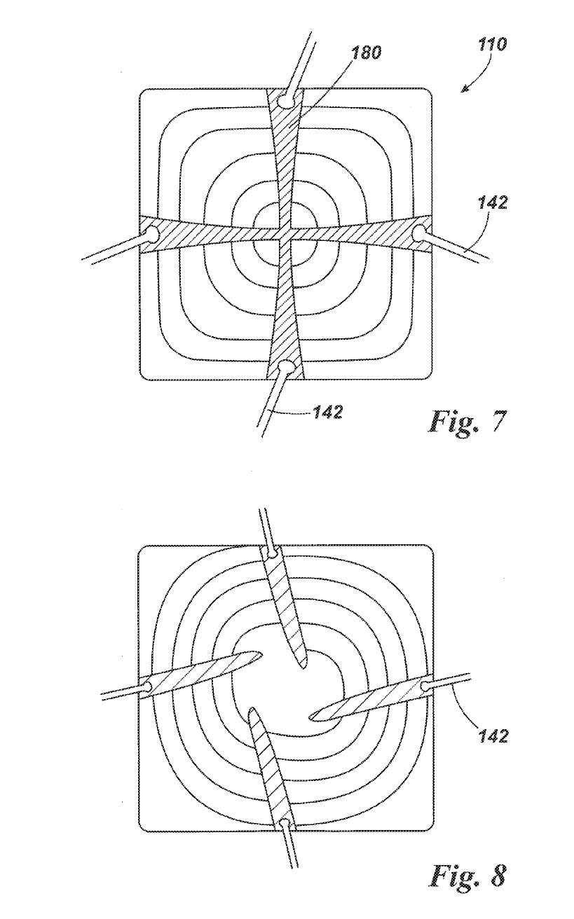

Another front plane electrode pattern is shown in FIG. 7. This is similar to the pattern of FIG. 4 with four busbar structures 180 elongate so as to extend radially towards the centre from central regions of each of the four sides of the cell. In this case, however, each busbar tapers in a concave manner towards the centre, thus allowing for the current from increasingly large surface area which each busbar must serve per unit length, as one moves in a direction from the centre to the periphery of the front surface. For a busbar servicing a triangular region of a cell, an approximately parabolic concave curvature of the taper may be appropriate. Assuming a constant current density across the triangular region, the total current to be carried by the busbar increases as a square of the distance from the triangle apex.

The four busbars of FIG. 7 are joined at the centre, to thereby allow current to flow into the centre along one or more, and out of the centre along the other busbars. This is will occur in the event that the concentrated illumination of the cell is uneven, and provides a significantly lower resistance path in this case than if the radial busbars did not interconnect.

Although particular forms of the front surface electrodes have been described, a number of variations may be envisaged. For example, although cells with one and four busbars have been described there may different numbers of busbar structures, such as two, three, and more than four. Although busbar shapes which are dart shaped and keyhole shaped, straight sided and convex sided, have been described, other shapes may be used. Where there are two or more busbars they may meet in a central region of the front surface, or may terminate without meeting.

The radially elongate busbars need not follow precise geometric radii of the cell, but may deviate for example as illustrated in FIG. 8.

An optical concentrator component must often carry out a high degree of concentration onto a small photovoltaic cell, and with a high proportion of the collected light falling within the boundaries of the cell. However, expensive optical systems may often be ruled out on financial grounds. The effect of concentration of light onto a photovoltaic cell is therefore very unlikely to provide a spatially even distribution of intensity at the front plane. Indeed, the intensity may vary by a factor of five or more across the front surface. Moreover, because the Sun is a moving light source, and the photovoltaic system must track the sun or allow for the movement, the distribution of intensity across the front surface of the cell is likely to change significantly with time, even if there are no other influences causing the system to move or change. As a result, the majority of the light falling on the cell may fall on only a relatively small part of the front surface. Of course, this effect is likely to become more acute where a cell of smaller surface area is used, and similarly at higher light concentrations.

The front surface electrode structures described improve the likelihood of a high intensity region falling on a part of the cell which is not appreciably shaded by a busbar structure, but which none-the-less is in close proximity to a busbar. In particular, cell efficiency and light harvesting efficiency are unlikely to be adversely affected by the extension of the radially elongated busbars into the centre of the cell.

Although specific embodiments of the invention have been described, the invention as defined by the claims is not limited to particular features of such embodiments, and a range of variations and modifications will be apparent to the skilled person.

What is claimed is:

1. A concentrator photovoltaic cell comprising:
a front plane through which light passes into the photovoltaic cell for the generation of a photocurrent;
a plurality of conductive gridlines disposed across the front plane so as to communicate the photocurrent with the front plane;
a plurality of separate conductive busbars disposed across the front plane and coupled to communicate the photocurrent with the gridlines, wherein each busbar comprises a bondpad region disposed at a periphery of the front plane for coupling the photocurrent to an external load, and wherein each busbar is elongate in a radial direction and extends into a central region of the front plane.

2. The cell of claim 1, wherein each busbar extends at least 40% of the distance across the cell in the radial direction.

3. The cell of claim 1, wherein each busbar tapers away from the periphery towards the central region of the front surface of the cell.

4. The cell of claim 1, wherein the area of the front plane is less than 200 mm².

5. The cell of claim 1, wherein the area of the front plane is less than 10 mm².

6. The cell of claim 1, wherein each bond pad region has dimensions in the front plane of between approximately 25 μm and 200 μm.

7. The cell of claim 1, wherein there are at least eight gridline connections to each busbar.

8. The cell of claim 1, wherein the gridlines cover an area that is at least 1% of the size of the area of the front plane that is not covered by gridlines and busbars.

9. The cell of claim 8, wherein the gridlines cover an area that is at least 10% of the size of the area of the front plane that is not covered by gridlines and busbars.

10. The cell of claim 1, wherein each busbar tapers in the radial direction towards the central region of the front plane.

11. The cell of claim 10, wherein each busbar is of a dart shape having a bondpad as a base at the periphery of the front plane of the cell and extending to an apex in the central region of the front plane.

12. The cell of claim 10, wherein the taper of each bus bar is concave along the majority of its length.

13. The cell of claim 1, further comprising a plurality of corresponding external wire connections coupled to the bondpad regions of the respective busbars for coupling the photocurrent with an external load.

14. The cell of claim 1, wherein the cell is monolithically formed of a plurality of epitaxially grown semiconductor layers.

15. The cell of claim 1, wherein the photovoltaic cell comprises a III-V semiconductor material junction configured to generate at least part of the electrical current.

16. The cell of claim 1, wherein the photovoltaic cell comprises one of a gallium arsenide substrate or a germanium substrate.

17. The cell of claim 1, wherein the photovoltaic cell comprises four busbars that extend across the front plane to form a “+” or “×” shape.

18. The cell of claim 1, wherein the photovoltaic cell comprises more than four busbars.

19. A solar photovoltaic system comprising:
a photovoltaic cell; and
an optical concentrator arranged to deliver sunlight having a concentrated intensity of at least one hundred suns to said photovoltaic cell;
wherein the photovoltaic cell comprises:
a front plane through which light passes into the photovoltaic cell for the generation of a photocurrent;
a plurality of conductive gridlines disposed across the front plane so as to communicate the photocurrent with the front plane;
a plurality of separate conductive busbars disposed across the front plane and coupled to communicate the photocurrent with the gridlines, wherein each busbar comprises a bondpad region disposed at a periphery of the front plane for coupling the photocurrent to an external load, and wherein each busbar is elongate in a radial direction and extends into a central region of the front plane.

20. The solar voltaic system of claim 19, wherein each busbar extends at least 40% of the distance across the cell in the radial direction.

21. The solar voltaic system of claim 19, wherein each busbar tapers away from the periphery towards the central region of the front surface of the cell.

22. The solar voltaic system of claim 19, wherein there are at least eight gridline connections to each busbar.

23. The solar voltaic system of claim 19, wherein the gridlines cover an area that is at least 1% of the size of the area of the front plane that is not covered by gridlines and busbars.

24. The solar voltaic system of claim 19, wherein each bus bar is concave along the majority of its length.

25. The solar voltaic system of claim 19, further comprising a plurality of corresponding external wire connections coupled to the bondpad regions of the respective busbars for coupling the photocurrent with an external load.

26. The solar voltaic system of claim 19, wherein the cell is monolithically formed of a plurality of epitaxially grown semiconductor layers.

27. The solar voltaic system of claim 19, wherein the photovoltaic cell comprises a III-V semiconductor material junction configured to generate at least part of the electrical current.

28. The solar voltaic system of claim 19, wherein the photovoltaic cell comprises one of a gallium arsenide substrate or a germanium substrate.

29. The solar voltaic system of claim 19, wherein the photovoltaic cell comprises four busbars that extend across the front plane to form a “+” or “×” shape.

30. The solar voltaic system of claim 19, wherein the photovoltaic cell comprises more than four busbars.

31. A solar photovoltaic system comprising:
a photovoltaic cell having a front surface with an area of less than 200 mm²; and
an optical concentrator arranged to receive incident sunlight and to deliver the sunlight concentrated by a factor of at least fifty to a front plane of the cell whereby the photovoltaic cell generates an electrical current;
wherein the photovoltaic cell further comprises:
a plurality of metallic gridline structures disposed at the front plane of the cell that are arranged to carry the electrical current into or out of the front plane; and
one or more separate radially elongate metallic busbars also disposed at the front plane of the cell and arranged to carry the electrical current to or from the gridline structures;
wherein each busbar extends from a peripheral region into a central region of the front surface of the cell.

32. The system of claim 31, wherein each of the busbars comprise two or more dart shaped busbars that taper from a broader peripheral bondpad region towards a narrower central tip region.

33. The system of claim 31, wherein the system is configured to generate an electrical current at the front plane in excess of 1 Amp per cm² area of the front plane.

34. The system of claim 31, wherein the photovoltaic cell comprises a III-V semiconductor material junction configured to generate at least part of the electrical current.

35. The system of claim 31, wherein the photovoltaic cell comprises one of a gallium arsenide substrate or a germanium substrate.

36. The system of claim 31, wherein the photovoltaic cell comprises four busbars that extend across the front plane to form a “+” or “×” shape.

37. The system of claim 31, wherein the photovoltaic cell comprises more than four busbars.
